(19) United States
(12) Patent Application Publication
(10) Pub. No.: US 2012/0107990 A1
(43) Pub. Date: May 3, 2012

(54) METHOD FOR MANUFACTURING SEMICONDUCTOR LIGHT EMITTING DEVICE AND SEMICONDUCTOR CRYSTAL GROWTH APPARATUS

(75) Inventor: Hideki Sekiguchi, Fukuoka-ken (JP)

(73) Assignee: KABUSHIKI KAISHA TOSHIBA, Tokyo (JP)

(21) Appl. No.: 13/170,244

(22) Filed: Jun. 28, 2011

(30) Foreign Application Priority Data
Oct. 27, 2010 (JP) 2010-241044

(51) Int. Cl. H01L 33/32; C23C 16/46; C23C 16/458; C23C 16/34

(52) U.S. Cl. 438/47; 118/725; 257/E33.023

(57) ABSTRACT

According to one embodiment, a method is disclosed for manufacturing a semiconductor light emitting device. The method can include a crystal growth process. The crystal growth process is configured to grow a stacked structure of compound semiconductor composed of a group III element and a group V element on a substrate by a metal organic chemical vapor deposition process. The substrate is mounted on a substrate mounting portion provided on a surface of a tray placed above a heating device. A compound semiconductor film includes at least one group III element forming the stacked structure and at least one group V element forming the stacked structure. The compound semiconductor film is previously formed on a surface of the substrate mounting portion before growing the stacked structure. The substrate is mounted on the substrate mounting portion via the compound semiconductor film, and the stacked structure is grown on the substrate.

### CROSS-REFERENCE TO RELATED APPLICATIONS

This application is based upon and claims the benefit of priority from the prior Japanese Patent Application No. 2010-241044, filed on Oct. 27, 2010; the entire contents of which are incorporated herein by reference.

### FIELD

Embodiments described herein relate generally to a method for manufacturing a semiconductor light emitting device and a semiconductor crystal growth apparatus.

### BACKGROUND

The process for manufacturing a semiconductor light emitting device such as a light emitting diode and semiconductor laser includes a process for crystal growing a mixed crystal semiconductor on a substrate by the metal organic chemical vapor deposition (MOCVD) process. In this mixed crystal semiconductor, a plurality of group III-V compound semiconductors are mixed in a certain ratio. InGaAlN-based nitride mixed crystal semiconductors, for instance, are used in white and blue light sources. InGaAlP-based mixed crystal semiconductors, for instance, are used in red to green light sources. GaAlAs-based mixed crystal semiconductors, for instance, are used in infrared light sources. Furthermore, InGaAsP-based mixed crystal semiconductors, for instance, are used in infrared light sources for telecommunications.

In Si-based semiconductor crystal growth, the crystal itself has high purity. Hence, it is necessary to prevent autodoping of impurity from the susceptor (or tray) supporting the crystal growth substrate in the crystal growth apparatus to the crystal being grown on the substrate. Thus, as an example, the substrate is mounted on a susceptor whose surface is previously covered with the same semiconductor film as the semiconductor to be crystal grown on the substrate. The Si-based semiconductor is then crystal grown on this substrate. However, in the crystal growth of the aforementioned group III-V mixed crystal semiconductors, the purity of the crystal itself is far lower than that of the Si-based semiconductor. Hence, there is no need to concern about autodoping from the susceptor during crystal growth. In the normal MOCVD process, a substrate is mounted on the surface of the susceptor made of e.g. carbon, quartz, or SIC. The substrate surface is heated through the susceptor by a heating means such as a heater. Here, in some crystal growth apparatuses, the substrate is mounted not directly on the susceptor, but on a tray mounted on the susceptor. In this case, the substrate surface is heated through the tray. A group III raw material and a group V raw material are supplied by a raw material supply means and react on this heated substrate surface. Thus, a crystal of group III-V mixed crystal semiconductor is grown on the substrate surface. In mixed crystal semiconductors such as InGaN composed of GaN and InN, the group III-V compound semiconductor is composed of a plurality of binary compound semiconductors. In such mixed crystal semiconductors, due to non-uniformity in surface temperature on the substrate, the composition (ratio in the crystal) of the group III element and the group V element of the group III-V compound semiconductor crystal grown on the substrate becomes non-uniform within the plane. Non-uniformity in crystal composition causes variation in the emission wavelength of the light emitting device. Thus, temperature uniformity on the substrate surface is important. Hence, covering the susceptor surface with a compound semiconductor film seems to cause non-uniformity in substrate surface temperature, and has been avoided.

### BRIEF DESCRIPTION OF THE DRAWINGS

FIGS. 1A and 1B show a tray used in a method for manufacturing a semiconductor light emitting device according to a first embodiment, FIG. 1A is a schematic top view, and FIG. 1B is a schematic sectional view;

FIG. 2 is a principal schematic sectional view of a part of a manufacturing process of the light emitting device according to the first embodiment;

FIGS. 3A and 3B show a tray used in a method for manufacturing a semiconductor light emitting device of a comparative example, FIG. 3A is a schematic top view, and FIG. 3B is a schematic sectional view;

FIGS. 4A and 4B show a part of a process for manufacturing a semiconductor light emitting device of the comparative example, FIG. 4A is a principal schematic top view, and FIG. 4B is a principal schematic sectional view;

FIGS. 5A and 5B show a tray to be used in the method for manufacturing the semiconductor light emitting device of the comparative example, FIG. 5A is a schematic top view, and FIG. 5B is a schematic sectional view;

FIG. 6 shows a principal schematic sectional view of a part of the process for manufacturing the semiconductor light emitting device of the comparative example; and

FIG. 7 is a principal schematic sectional view of a part of a process for manufacturing a semiconductor light emitting device according to a second embodiment.

### DETAILED DESCRIPTION

In general, according to one embodiment, a method is disclosed for manufacturing a semiconductor light emitting device. The method can include a crystal growth process. The crystal growth process is configured to grow a stacked structure of compound semiconductor composed of a group III element and a group V element on a substrate by a metal organic chemical vapor deposition process. The substrate is mounted on a substrate mounting portion provided on a surface of a tray placed above a heating device. The surface is located on a side opposite to the heating device. A compound semiconductor film includes at least one group III element forming the stacked structure of the compound semiconductor and at least one group V element forming the stacked structure of the compound semiconductor. The compound semiconductor film is previously formed on a surface of the substrate mounting portion before growing the stacked structure. The substrate is mounted on the substrate mounting portion via the compound semiconductor film, and the stacked structure is grown on the substrate.

Various embodiments will be described hereinafter with reference to the accompanying drawings. The figures used in describing the embodiments are schematic for ease of description. The shape, dimension, and size relation of components in the figures do not necessarily need to be identical to those shown in the figures when they are actually put into practice, but can be suitably modified as long as the effect of the invention is achieved. Embodiments are described with a case where a light emitting diode is manufactured using InGaAlN nitride mixed crystal semiconductor having InN, GaN, AlN mixed with a prescribed ratio as group III-V compound semiconductor taken as an example. Similar description is possible on other compound mixed crystal semiconductors such as InGaAlP-based, GaAlAs-based, and InGaAsP-based compound semiconductor or the like. The term InGaAlN-based nitride semiconductor is taken as including binary compound semiconductor such as InN, GaN and AlN (case where other binary compound ratio is zero) and those mixed crystals. The III-V group compound semiconductor of other materials is similarly taken as including respective group III-V binary compound semiconductors and those mixed crystals.

### First Embodiment

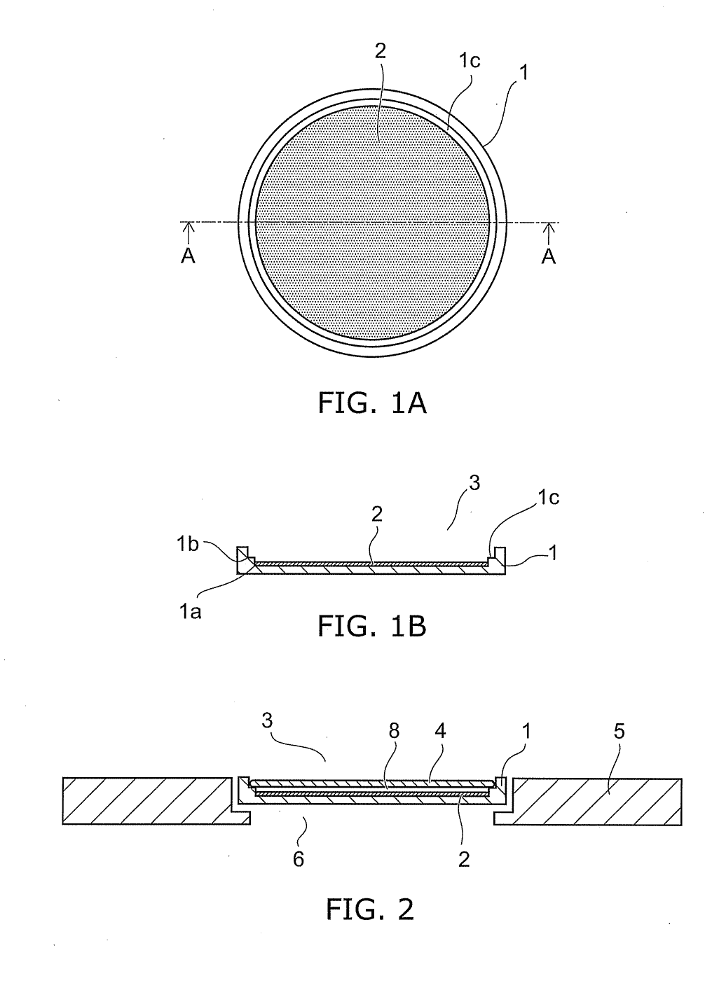

A first embodiment is described with reference to FIGS. 1A and 1B. FIGS. 1A and 1B show a tray used to mount a substrate in the crystal growth process constituting part of a method for manufacturing a semiconductor light emitting device according to the first embodiment. FIG. 1A is a schematic top view, and FIG. 1B is a schematic sectional view taken along line A-A of FIG. 1A. FIG. 2 shows the principal part of the crystal growth process in which the tray mounting the substrate is mounted on a susceptor. FIG. 2 is a schematic sectional view at the position corresponding to the position of line A-A of FIG. 1A. The method for manufacturing a semiconductor light emitting device according to the embodiment is described, by way of example, as a method for manufacturing a nitride semiconductor light emitting diode. The method for manufacturing a semiconductor light emitting device according to the embodiment includes a crystal growth process for growing a stacked structure of group III-V compound semiconductor on a substrate by the MOCVD process, and the existing lithography process, etching process, and electrode formation process used to manufacture a light emitting diode or semiconductor laser. The stacked structure of compound semiconductor is grown by the MOCVD process to achieve a desired structure of the light emitting diode or semiconductor laser as designed. Thus, the semiconductor light emitting device is manufactured. The method for manufacturing a semiconductor light emitting device according to the embodiment is characterized by the crystal growth process for growing a stacked structure of group III-V compound semiconductor by the MOCVD process. In the following, this MOCVD-based crystal growth process is described in detail, and the description of the other processes is omitted.

By the MOCVD process, the stacked structure of group III-V compound semiconductor is grown as follows. The MOCVD-based crystal growth apparatus includes, although not shown, at least a heating means, a susceptor, a tray, and a raw material supply means. The heating means may be based on the so-called heater heating in which a current is passed in a resistor. However, it is understood that lamp heating can also be used. A susceptor including a plurality of openings is placed above the heating means. A tray is mounted in each of these openings. On the tray is mounted a substrate on which a stacked structure of group III-V compound semiconductor is to be grown.

In the crystal growth process of the method for manufacturing a semiconductor light emitting device according to the embodiment, the tray 1 shown in FIGS. 1A and 1B is used. The tray 1 is made of e.g. SiC, quartz, or carbon and processed into the shape shown in FIGS. 1A and 1B. Here, in the crystal growth of nitride semiconductor, carbon reacts with nitrogen (N) raw materials, and hence a tray made of e.g. SiC or quartz is used. The tray 1 is shaped like a disc having a larger diameter than the substrate 4 to be mounted thereon. The tray 1 includes a depression 1a formed in a circular shape on the first surface (upper surface in FIG. 1B). The tray 1 further includes a step difference 1b formed at the upper end of the sidewall of this depression 1a so that the step difference 1b contours the depression along the sidewall. The step difference 1b is formed from a middle step 1c and a sidewall. The middle step is formed in the upper portion of the sidewall of the depression 1a at height positions between the first surface of the tray 1 and the bottom surface of the depression 1a. The sidewall of the step difference 1b is a wall connecting the middle step 1c and the first surface of the tray 1. As viewed from above the first surface, the sidewall of the step difference 1b is formed annularly or circularly along and outside the circular outer periphery of the depression 1a. That is, the depression 1a is contained inside the circle that the sidewall of the step difference 1b delineates on the first surface. The portion including the depression 1a and the step difference 1b constitutes a substrate mounting portion 3. As shown in FIG. 2, a substrate 4 is mounted on the substrate mounting portion 3. The substrate mounting portion 3 includes the aforementioned middle step is formed from the step difference 1b in the sidewall upper portion of the depression 1a.

A compound semiconductor film 2 is formed on the bottom surface of the depression 1a. In the embodiment, as a stacked structure of group III-V compound semiconductor, a stacked structure of InGaAlN-based nitride semiconductor is formed on the substrate 4 by the MOCVD-based crystal growth process. In this case, this compound semiconductor film 2 can be made of a nitride semiconductor containing at least one group III element constituting this stacked structure, i.e., at least one group III element of In, Ga, and Al, and a group V element, N. For instance, the compound semiconductor film 2 is formed from GaN. The compound semiconductor film 2 may be formed using the aforementioned MOCVD-based crystal growth apparatus for subsequently growing a stacked structure of nitride semiconductor. Alternatively, the compound semiconductor film 2 may be formed by another MOCVD-based crystal growth apparatus, or by an apparatus of other deposition processes such as a sputtering apparatus.

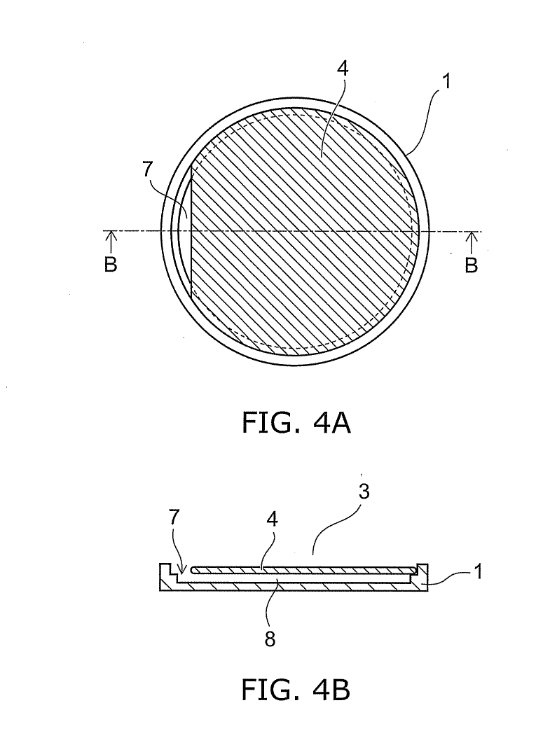

As shown in FIG. 2, the substrate 4 is mounted inside this step difference 1b. The outer peripheral portion of the substrate 4 is supported by the middle step 1c. Thus, the substrate 4 is spaced from the aforementioned compound semiconductor film 2 via a gap 8. Here, the substrate 4 includes an orientation flat, not shown. As shown in FIG. 4A described later, the orientation flat and the tray 1 constitute an opening 7. The tray 1, with the substrate 4 mounted thereon, is mounted on a tray mounting portion 6 where the opening of the susceptor 5 is formed. The tray 1 can rotate on its axis with respect to the susceptor 5. The susceptor 5 can be made of the same material as the tray 1.

The aforementioned heating means, not shown, is placed below the susceptor 5. The heating means supplies heat to the substrate 4 through the tray 1 mounted on the tray mounting portion 6 of the susceptor 5, the compound semiconductor film 2 formed on the bottom surface of the depression 1a of the substrate mounting portion 3 of the tray 1, and the gap 8. Here, in the entire surface of the substrate 4, heat is supplied from the heating means to the substrate through the compound semiconductor film 2 located between the substrate and the bottom surface of the depression of the tray 1. By this heat, the surface of the substrate 4 is heated. The group III raw material and the group V raw material supplied from the aforementioned raw material supply means undergo chemical reaction on the heated substrate surface. Thus, a stacked structure of InGaAlN-based nitride semiconductor is grown. Here, the detailed description of the stacked structure is omitted. For instance, in the aforementioned crystal growth process, a double heterostructure is formed on a sapphire substrate 4. In this double heterostructure, an active layer made of InGaN nitride mixed crystal semiconductor is sandwiched between cladding layers made of GaN. Subsequently, the existing process for forming a light emitting diode is performed to form a semiconductor light emitting device. To form a blue light emitting diode having an emission wavelength in the 450-nm band, the In composition of InGaN in the aforementioned active layer can be set to 20% of the entire group III raw material. That is, InGaN of the active layer is crystal grown so that the ratio (mole fraction) of InN/(InN+GaN) is 0.2.

The variation of emission wavelength of the completed light emitting diode depends on the variation of In composition of InGaN of the active layer. Hence, the variation of emission wavelength of the light emitting diode can be suppressed by suppressing the variation of In composition ratio of InGaN of the active layer in the substrate surface. The maximum and minimum of the In composition of InGaN of the active layer in the substrate surface are denoted by Max and Min, respectively. The variation thereof is defined as (Max−Min)/(Max+Min). Then, the variation of In composition of InGaN of the active layer grown by the aforementioned crystal growth process of the method for manufacturing a semiconductor light emitting device according to the embodiment was as small as 5%.

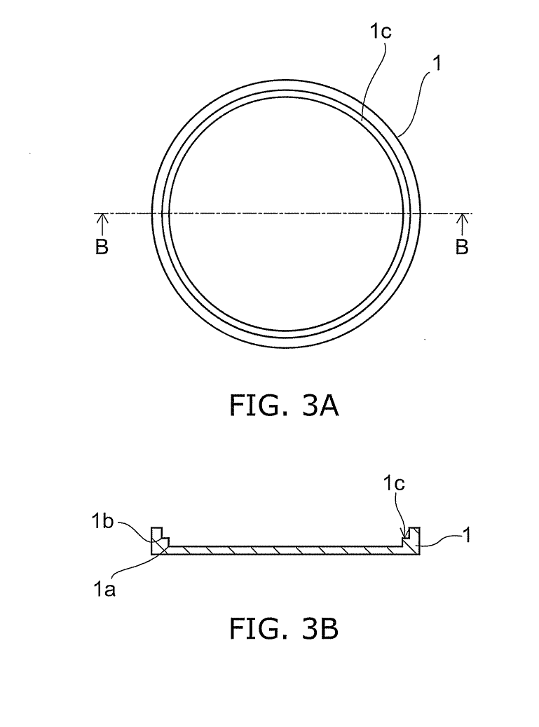

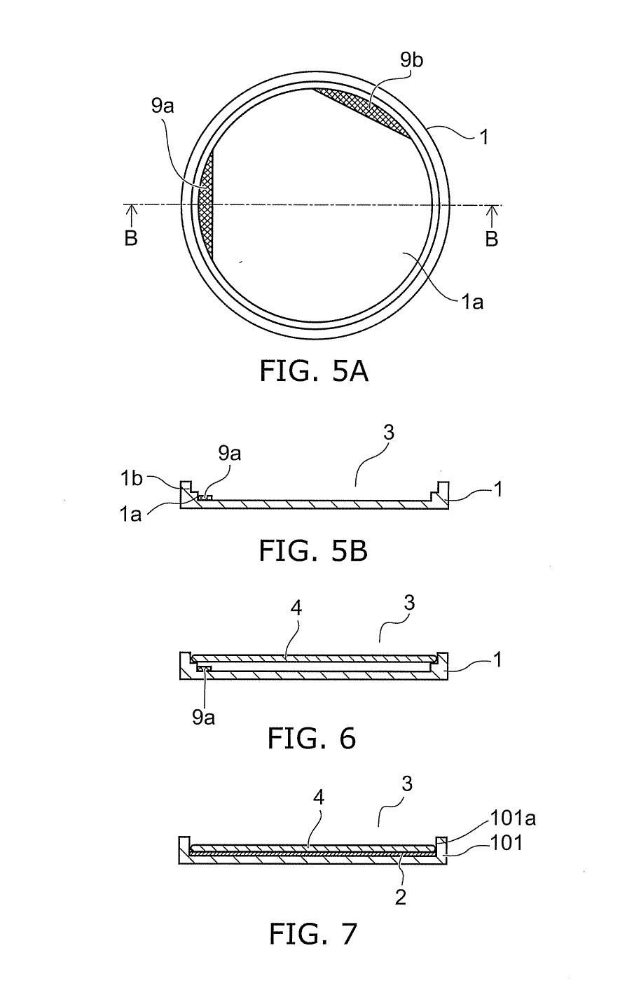

To demonstrate that this variation is small, a similar double heterostructure for comparison was formed by a crystal growth process constituting part of a method for manufacturing a semiconductor light emitting device of a comparative example. The method for manufacturing a semiconductor light, emitting device of the comparative example is described with reference to FIGS. 3A to 6. Here, the portions having the same configuration as those described in the embodiment are labeled with like reference numerals or symbols, and the description thereof is omitted. Differences from the embodiment are primarily described. FIGS. 3A and 3B show a tray to be used in the method for manufacturing a semiconductor light emitting device of the comparative example. FIG. 3A is a schematic top view, and FIG. 3B is a schematic sectional view taken along line B-B of FIG. 3A. FIGS. 4A and 4B show part of the process for manufacturing a semiconductor light emitting device of the comparative example. FIG. 4A is a principal schematic top view, and FIG. 4B is a principal schematic sectional view taken along line B-B of FIG. 4A. FIGS. 5A and 5B show a tray after use in the method for manufacturing a semiconductor light emitting device of the comparative example. FIG. 5A is a schematic top view, and FIG. 5B is a schematic sectional view taken along line B-B of FIG. 5A. FIG. 6 shows part of the process for manufacturing a semiconductor light emitting device of the comparative example using the tray after use shown in FIGS. 5A and 5B. FIG. 6 is a principal schematic sectional view at the position corresponding to line B-B of FIG. 5A.

The method for manufacturing a semiconductor light emitting device of the comparative example is generally the same as the method for manufacturing a semiconductor light emitting device according to the embodiment except for the structure of the tray for mounting a substrate. In the following, the difference in the structure of the tray, and the MOCVD-based crystal growth process using this tray are described.

Like the tray 1 used in the embodiment, the tray 1 used in the comparative example is made of e.g. SIC, quartz, or carbon and processed into the shape shown in FIGS. 3A and 3B. The tray 1 is shaped like a disc having a larger diameter than the substrate 4 to be mounted thereon. The tray 1 includes a depression 1a formed in a circular shape on the first surface (upper surface in FIG. 3B). The tray 1 further includes a step difference 1b formed at the upper end of the sidewall of this depression 1a so that the step difference 1b contours the depression along the sidewall. The step difference 1b is formed from a middle step 1c and a sidewall. The middle step 1c is formed in the upper portion of the sidewall of the depression 1a at height positions between the first surface of the tray 1 and the bottom surface of the depression 1a. The sidewall of the step difference 1b is a wall connecting the middle step 1c and the first surface of the tray 1. As viewed from above the first surface, the sidewall of the step difference 1b is formed annularly or circularly along and outside the circular outer periphery of the depression 1a. That is, the depression 1a is contained inside the circle that the sidewall of the step difference 1b delineates on the first surface. The portion including the depression 1a and the step difference 1b constitutes a substrate mounting portion 3. As shown in FIG. 2, a substrate 4 is mounted on the substrate mounting portion 3. The substrate mounting portion 3 includes the aforementioned middle step 1c formed from the step difference 1b in the sidewall upper portion of the depression 1a.

In contrast to the tray 1 used in the first embodiment, the compound semiconductor film 2 is not formed on the bottom surface of the depression 1a. That is, the bottom surface of the depression 1a is exposed. The tray 1 used in the embodiment includes a compound semiconductor film 2 formed on the entire bottom surface of the depression 1a of the substrate mounting portion 3. In contrast, the tray 1 used in the comparative example does not include the compound semiconductor film 2 formed on the entire bottom surface of the depression 1a of the substrate mounting portion 3. This is the difference between the method for manufacturing a semiconductor light emitting device according to the embodiment and the method for manufacturing a semiconductor light emitting device of the comparative example. The remaining configuration is the same.

The MOCVD-based crystal growth process for growing a stacked structure of InGaAlN-based nitride semiconductor using the aforementioned tray is described. This process is one process of the method for manufacturing a semiconductor light emitting device of the comparative example. As shown in FIGS. 4A and 4B, as in the embodiment, a sapphire substrate 4 including an orientation flat is mounted on the substrate mounting portion 3 of the aforementioned tray 1. The outer peripheral edge of the substrate 4 is supported by the middle step is of the tray 1 so that the substrate 4 is spaced from the bottom surface of the depression is of the tray 1 via a gap 8. An opening 7 is formed between the orientation flat of the substrate 4 and the middle step 1c of the tray 1. In this state, as in the embodiment, the tray 1 is mounted on the tray mounting portion 6 of the susceptor 5 as shown in FIG. 2. By the MOCVD process, a stacked structure of InGaAlN-based nitride semiconductor is grown in a procedure similar to that of the embodiment.

FIGS. 5A and 5B show the situation on the bottom surface of the depression 1a of the tray 1 after completion of the MOCVD-based crystal growth. On the bottom surface of the depression 1a of the tray 1, an InGaAlN-based nitride semiconductor deposit 9a is formed at a position corresponding to the orientation flat of the substrate 4. This results from the fact that during crystal growth, the raw material of InGaAlN-based nitride semiconductor flows onto the bottom surface of the depression is through the opening 7 formed between the orientation flat of the substrate 4 and the middle step is of the tray 1 and causes chemical reaction. Next, the tray 1 used in the aforementioned crystal growth process is used again to grow a stacked structure of InGaAlN-based nitride semiconductor on another substrate 4 by the MOCVD process. Then, as in the foregoing, an InGaAlN-based nitride semiconductor deposit 9b is formed on the bottom surface of the depression 1a of the tray 1 at a position different from that of the aforementioned nitride semiconductor deposit 9a. A reason for this is that, before crystal growth, the present substrate 4 is mounted on the tray 1 so that the orientation flat of the substrate 4 for the present crystal growth is located at a position different from the position of the orientation flat of the substrate 4 mounted in the previous crystal growth. Another reason is that after the substrate 4 is mounted on the tray 1, by vibration due to the aforementioned rotation of the tray 1 on its axis during crystal growth, the substrate 4 rotates on its axis on the substrate mounting portion 3 of the tray 1.

Thus, if the tray 1 is used many times in the MOCVD-based crystal growth, then as shown in FIGS. 5A and 5B, InGaAlN-based nitride semiconductor deposits (9a, 9b) are formed non-uniformly along the outer periphery on the bottom surface of the depression 1a of the tray 1. The method for manufacturing a semiconductor light emitting device according to the embodiment is different from the method for manufacturing a semiconductor light emitting device of the comparative example in whether the compound semiconductor film 2 is formed on the entire bottom surface of the depression. Hence, such InGaAlN-based nitride semiconductor deposits (9a, 9b) are formed not only in the comparative example but also in the embodiment. However, in the case of the embodiment, before growing a stacked structure of InGaAlN-based nitride semiconductor, the compound semiconductor film 2 is previously formed on the entire bottom surface of the depression is of the tray 1. The compound semiconductor film 2 is made of a nitride semiconductor containing at least one group III element constituting this stacked structure of nitride semiconductor, i.e., at least one group III element of In, Ga, and Al, and a group V element, N. In the embodiment, for instance, the compound semiconductor film 2 is formed from GaN. Hence, even if InGaAlN-based nitride semiconductor deposits (9a, 9b) are formed non-uniformly along the outer periphery on the bottom surface of the depression is of the tray 1, the InGaAlN-based nitride semiconductor deposits are formed on the entire bottom surface of the depression 1a, although there is difference in the composition of the group III element. Thus, the amount of heat supplied from the heating means to the surface of the substrate 4 through the bottom surface of the depression is of the tray 1 and the gap 8 is made nearly uniform across the entire surface of the substrate 4. As a result, as described above, in the active layer of the light emitting diode grown by the MOCVD-based crystal growth process of the method for manufacturing a semiconductor light emitting device according to the embodiment, the In composition of InGaN was uniform in the surface of the substrate 4.

In contrast, in the MOCVD-based crystal growth process of the comparative example, when a substrate 4 is mounted on the substrate mounting portion 3 of the tray 1 as shown in FIG. 6, InGaAlN-based nitride semiconductor deposits (9a, 9b) exist non-uniformly on the outer peripheral portion on the bottom surface of the depression 1a. However, in the remaining portion, the material of the tray 1 is exposed at the surface of the depression 1a. As a result, in the outer peripheral portion of the depression, the amount of heat supplied from the heating means is supplied through the aforementioned InGaAlN-based nitride semiconductor deposits (9a, 9b). However, in the remaining portion, the amount of heat is supplied directly through the bottom surface of the depression of the tray 1. The material of the tray 1 and the InGaAlN-based nitride semiconductor deposits (9a, 9b) are greatly different in the efficiency of transferring heat to the substrate 4. Hence, as compared with the MOCVD-based crystal growth process of the embodiment, the temperature is made non-uniform on the surface of the substrate 4 in the comparative example.

By the MOCVD-based crystal growth process in the method for manufacturing a semiconductor light emitting device of the comparative example, a double heterostructure was formed on a sapphire substrate 4 as in the embodiment. In this double heterostructure, an active layer made of InGaN nitride mixed crystal semiconductor is sandwiched between cladding layers made of GaN. As a result, the variation of In composition of InGaN of the active layer is 15%. This is significantly greater than the variation, 5%, of that grown by the MOCVD-based crystal growth process of the embodiment. It is considered that this results from the non-uniformity of surface temperature of the substrate 4 during crystal growth for the aforementioned reasons.

As described above, in the method for manufacturing a semiconductor light emitting device according to the embodiment, before a stacked structure of InGaAlN-based nitride semiconductor is grown on the substrate by the MOCVD process, a compound semiconductor film 2 is previously formed on the entire surface of the substrate mounting portion of the tray. The compound semiconductor film 2 is made of a nitride semiconductor containing at least one group III element constituting this stacked structure of nitride semiconductor, i.e., at least one group III element of In, Ga, and Al, and a group V element, N. Hence, even if InGaAlN-based nitride semiconductor deposits (9a, 9b) are formed non-uniformly along the outer periphery on the bottom surface of the depression is of the tray 1, the InGaAlN-based nitride semiconductor deposits are formed on the entire bottom surface of the depression, although there is difference in the composition of the group III element. Thus, the amount of heat supplied from the heating means to the surface of the substrate 4 through the bottom surface of the depression 1a of the tray 1 and the gap 8 is made nearly uniform across the entire surface of the substrate 4. Consequently, as an advantageous effect, the composition of the nitride mixed crystal semiconductor in the stacked structure of InGaAlN-based nitride semiconductor grown by the MOCVD-based crystal growth process of the method for manufacturing a semiconductor light emitting device according to the embodiment is uniform in the surface of the substrate 4.

In the above description of the embodiment, a stacked structure of InGaAlN-based nitride semiconductor is grown on a substrate by the MOCVD process. In the case of growing a stacked structure of InGaAlP-based compound semiconductor, the compound semiconductor film 2 can be made of a compound semiconductor containing at least one group III element of In, Ga, and Al, and a group V element, phosphorus (P). The compound semiconductor film 2 is previously formed on the substrate mounting portion of the tray 1 before crystal growth. Then, the aforementioned effect of the embodiment is achieved. In the case of growing a stacked structure of GaAlAs-based compound semiconductor, the compound semiconductor film 2 can be made of a compound semiconductor containing at least one group III element of Ga and Al, and a group V element, arsenic (As). The compound semiconductor film 2 is previously formed on the substrate mounting portion of the tray 1 before crystal growth. Then, the effect of the embodiment is achieved. In the case of growing a stacked structure of InGaAsP-based compound semiconductor, the compound semiconductor film 2 can be made of a compound semiconductor containing at least one group III element of In and Ga, and at least one group V element of As and P. The compound semiconductor film 2 is previously formed on the substrate mounting portion of the tray 1 before crystal growth. Then, the effect of the embodiment is achieved. In general, in the case of growing a stacked structure of group III-V compound semiconductor, a group III-V compound semiconductor containing at least one of the group III elements contained in this stacked structure, and at least one of the group V elements contained in this stacked structure is previously formed on the substrate mounting portion of the tray 1 before crystal growth. Then, the effect of the embodiment is achieved.

### Second Embodiment

A method for manufacturing a semiconductor light emitting device according to a second embodiment is described with reference to FIG. 7. Here, the portions having the same configuration as those described in the first embodiment are labeled with like reference numerals or symbols, and the description thereof is omitted. Differences from the first embodiment are primarily described. FIG. 7 is a principal schematic sectional view of part of the process for manufacturing a semiconductor light emitting device according to the second embodiment. The method for manufacturing a semiconductor light emitting device according to the embodiment is different from the manufacturing method of the first embodiment in the structure of the tray 1 used in the MOCVD-based crystal growth process for growing a stacked structure of InGaAlN-based nitride semiconductor. The remaining configuration is the same as that of the method for manufacturing a semiconductor light emitting device according to the first embodiment. FIG. 7 shows the state of the substrate 4 mounted on the tray 1 in the MOCVD-based crystal growth process, and corresponds to FIG. 2 of the first embodiment. Here, the figure showing the tray 101 mounted on the susceptor 5 is omitted. The tray 101 used in the method for manufacturing a semiconductor light emitting device of the embodiment is different in structure from the tray 1 used in the first embodiment in that the tray 101 includes only the depression is formed on the first surface, and does not include the step difference 1b at the upper end of the sidewall of the depression 1a. That is, in the tray 101 used in the method for manufacturing a semiconductor light emitting device of the embodiment, the substrate mounting portion 3 is constituted only by the depression 101a. The compound semiconductor film 2 shown in the above first embodiment is formed on the entire bottom surface of the depression 101a of the tray 101. The substrate 4 is mounted on the compound semiconductor film 2 in the depression 101a so as to be in contact with the compound semiconductor film 2.

Also in the method for manufacturing a semiconductor light emitting device of the embodiment, before a stacked structure of InGaAlN-based nitride semiconductor is grown on the substrate by the MOCVD process, a compound semiconductor film 2 is previously formed on the entire surface of the substrate mounting portion of the tray. The compound semiconductor film 2 is made of a nitride semiconductor containing at least one group III element constituting this stacked structure of nitride semiconductor, i.e., at least one group III element of In, Ga, and Al, and a group V element, N. Hence, an effect similar to that of the first embodiment can be achieved. Furthermore, as described in the first embodiment, in general, in the case of growing a stacked structure of group III-V compound semiconductor, a group III-V compound semiconductor containing at least one of the group III elements contained in this stacked structure, and at least one of the group V elements contained in this stacked structure is previously formed on the substrate mounting portion of the tray 1 before crystal growth. Then, the effect of the embodiment is achieved.

In the examples described above, in the MOCVD-based crystal growth process in each embodiment, the tray (1, 101) mounting the substrate 4 is further mounted on the tray mounting portion 6 of the susceptor 5. In the examples of each embodiment described above, for simplicity of description, a single tray is mounted on the susceptor. However, it is understood that a plurality of trays can be mounted on the susceptor. Furthermore, the tray itself can be used as a susceptor. That is, the surface of the tray may be large enough to mount a plurality of substrates 4. In this case, the surface of the tray includes a plurality of substrate mounting portions 3. Each substrate mounting portion 3 may be formed to include the depression 1a and the step difference 1b shown in the first and second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor light emitting device, comprising:
a crystal growth process configured to grow a stacked structure of compound semiconductor composed of a group III element and a group V element on a substrate by a metal organic chemical vapor deposition process, the substrate being mounted on a substrate mounting portion provided on a surface of a tray placed above a heating device, the surface being located on a side opposite to the heating device,
a compound semiconductor film including one group III element forming the stacked structure of the compound semiconductor and one group V element forming the stacked structure of the compound semiconductor being previously formed on a surface of the substrate mounting portion before growing the stacked structure, the substrate being mounted on the substrate mounting portion via the compound semiconductor film, and the stacked structure being grown on the substrate.

2. The method according to claim 1, wherein the substrate mounting portion includes a depression formed on the surface of the tray, and the compound semiconductor film is formed entirely on a bottom surface of the depression.

3. The method according to claim 2, wherein the substrate mounting portion further includes a step difference at an upper end of a sidewall of the depression so as to contour the depression.

4. The method according to claim 3, wherein a middle step is formed by the step difference at the sidewall of the depression, and the substrate is supported by the middle step so that the substrate is spaced from the compound semiconductor film.

5. The method according to claim 1, wherein on the surface as viewed from the side opposite to the heating device, the compound semiconductor film formed on the substrate mounting portion is not formed outside the substrate.

6. The method according to claim 1, wherein with the tray further mounted in an opening of a susceptor, the stacked structure of the compound semiconductor is grown.

7. The method according to claim 1, wherein each layer of the stacked structure of the compound semiconductor is made of a nitride semiconductor in which the group III element includes at least one element of In, Al, and Ga, and the group V element includes N.

8. The method according to claim 2, wherein the compound semiconductor film is made of GaN.

9. The method according to claim 2, wherein the substrate is in contact with the compound semiconductor film.

10. A semiconductor crystal growth apparatus for growing a stacked structure of compound semiconductor composed of a group III element and a group V element on a substrate by a metal organic chemical vapor deposition process, the apparatus comprising:
a heating device;
a tray placed above the heating device and including a substrate mounting portion configured to mount the substrate on a surface located on a side opposite to the heating device; and
a raw material supply device,
a compound semiconductor film including one group III element forming the stacked structure of the compound semiconductor and one group V element forming the stacked structure of the compound semiconductor being formed on a surface of the substrate mounting portion.

11. The apparatus according to claim 10, wherein the substrate mounting portion includes a depression formed on the surface of the tray, and the compound semiconductor film is formed entirely on a bottom surface of the depression.

12. The apparatus according to claim 11, wherein the substrate mounting portion further includes a step difference at an upper end of a sidewall of the depression so as to contour the depression.

13. The apparatus according to claim 12, wherein a middle step is formed by the step difference at the sidewall of the depression, and the substrate is supported by the middle step so that the substrate is spaced from the compound semiconductor film.

14. The apparatus according to claim 10, wherein on the surface as viewed from the side opposite to the heating device, the compound semiconductor film formed on the substrate mounting portion is not formed outside the substrate.

15. The apparatus according to claim 10, further comprising:
a susceptor including an opening,
the tray being mounted in the opening of the susceptor.

16. The apparatus according to claim 10, wherein each layer of the stacked structure of the compound semiconductor is made of a nitride semiconductor in which the group III element includes at least one element of In, Al, and Ga, and the group V element includes N.

17. The apparatus according to claim 11, wherein the compound semiconductor film is made of GaN.

18. The apparatus according to claim 11, wherein the substrate is in contact with the compound semiconductor film.
